(19) United States
(12) Patent Application Publication
(10) Pub. No.: US 2014/0023803 A1
(43) Pub. Date: Jan. 23, 2014

(54) AIRTIGHT MEMBER AND ITS PRODUCTION PROCESS

(71) Applicant: ASAHI GLASS COMPANY, LIMITED, Chiyoda-ku (JP)

(72) Inventors: Sohei KAWANAMI, Chiyoda-ku (JP); Akihiro Hishinuma, Koriyama-shi (JP)

(73) Assignee: ASAHI GLASS COMPANY, LIMITED, Chiyoda-ku (JP)

(21) Appl. No.: 14/012,388

(22) Filed: Aug. 28, 2013

Related U.S. Application Data
(63) Continuation of application No. PCT/JP2012/054645, filed on Feb. 24, 2012.

(30) Foreign Application Priority Data
Feb. 28, 2011 (JP) 2011-041416

(51) Int. Cl. H05K 5/06

(52) U.S. Cl. CPC H05K 5/06
USPC 428/34; 156/272.2

(57) ABSTRACT

To provide a process for producing an airtight member, which can improve bonding property of a sealing layer to a highly thermally conductive substrate and reliability, in airtight sealing of a space between a glass substrate and a highly thermally conductive substrate by local heating by electromagnetic waves.

A glass substrate having a sealing material layer having electromagnetic wave absorbing property provided on a sealing region, and a highly thermally conductive substrate having a glass layer formed on a sealing region, are laminated while the sealing material layer and the glass layer are brought into contact with each other. The sealing material layer is irradiated with electromagnetic waves through the glass substrate to heat and melt the sealing material layer thereby to bond it to the glass layer, so as to form a sealing layer which airtightly seals the space between the glass substrate and the thermally conductive substrate.

### TECHNICAL FIELD

The present invention relates to an airtight member and its production process.

### BACKGROUND ART

To a package in which an electronic element such as a quartz oscillator, a piezoelectric element, a filter element, a sensor element, an imaging element, an organic EL element or a solar battery element is airtightly sealed, for example, a package structure using a glass substrate for a base substrate on which the electronic element is to be formed or mounted, and using a highly thermally conductive substrate made of a metal material or ceramic material excellent in the heat dissipation property, for a cover substrate which airtightly seals the electronic element, has been applied. Further, to a package in which a light-receiving element such as an imaging element or a light-emitting element such as an organic EL element is airtightly sealed, e.g. a package structure using a highly thermally conductive substrate for a base substrate and using a transparent glass substrate for a cover substrate has also been applied.

As a sealing material to airtightly seal the space between a highly thermally conductive substrate comprising e.g. a metal material or a ceramic material and a glass substrate, a sealing resin or sealing glass has been used. Since a sealing resin is inferior in the moisture resistance, the weather resistance and the like to sealing glass, sealing glass excellent in the moisture resistance and the like is employed in an application such that the airtight sealing property or the like of an electronic element should be increased. Patent Document 1 discloses to seal a base substrate comprising a glass substrate or the like and a rid made of a metal by using a sealing material comprising low-melting glass. Here, the sealing material layer comprising low-melting glass is irradiated with e.g. laser light through the glass substrate to locally heat and melt the sealing material layer, and the base substrate and the rid made of a metal are sealed by means of a melt bonded layer (sealing layer) of the sealing material.

In a case where local heating e.g. by laser light is applied to airtight sealing of the space between the glass substrate and the highly thermally conductive substrate, since the highly thermally conductive substrate such as a metal substrate or a ceramic substrate has a higher coefficient of thermal conductivity as compared with the glass substrate, heat generated when the sealing material layer containing low-melting glass is irradiated with e.g. laser light escapes to the highly thermally conductive substrate side, whereby the sealing material layer cannot favorably be bonded to the highly thermally conductive substrate. Further, even if the melt bonded layer (sealing layer) of the sealing material layer and the highly thermally conductive substrate can be bonded, a stress applied to the glass substrate or the sealing layer tends to be significant due to thermal expansion based on a difference in thermal conductivity between the low-melting glass as the main component of the sealing material layer and the highly thermally conductive substrate. The stress applied to the glass substrate or the sealing layer may cause cracks or breakage to the sealing layer or the glass substrate, or may cause a decrease in the strength at the sealing portion between the glass substrate and the highly thermally conductive substrate and the reliability.

### PRIOR ART DOCUMENT

### Patent Document

Patent Document 1: JP-A-2003-046012

### DISCLOSURE OF INVENTION

### Technical Problem

The object of the present invention is to provide a process for producing an airtight member which can increase the bonding property of a sealing layer which is a melt bonded layer of a glass material for sealing to a highly thermally conductive substrate, and the reliability, in airtight sealing of a space between a glass substrate and a highly thermally conductive substrate by employing local heating e.g. by laser light, and an airtight member prepared by such a production process.

### Solution to Problem

The process for producing an airtight member of the present invention comprises a step (hereinafter sometimes referred to as step A) of preparing a glass substrate having a first surface having a first sealing region and a sealing material layer comprising a fired layer of a glass material for sealing having an electromagnetic wave absorbing property, formed on the first sealing region; a step (hereinafter sometimes referred to as step B) of preparing a highly thermally conductive substrate having a second surface having a second sealing region corresponding to the first sealing region and a glass layer formed on the second sealing region; a step (hereinafter sometimes referred to as step C) of laminating the glass substrate and the highly thermally conductive substrate while the first surface and the second surface are brought to face each other and the sealing material layer and the glass layer are brought into contact with each other; and a step (hereinafter sometimes referred to as step D) of irradiating the sealing material layer with electromagnetic waves through the glass substrate to locally heat and melt the sealing material layer thereby to bond it to the glass layer, so as to form a sealing layer which airtightly seals the space between the glass substrate and the highly thermally conductive substrate.

In the above process for producing an airtight member of the present invention, the order of the steps A and B is not limited, and either may be carried out first, or both may be carried out simultaneously. In the step C, the glass substrate and the highly thermally conductive substrate obtained in the steps A and B are laminated, and the step D follows the step C.

The airtight member of the present invention comprises a glass substrate having a first surface having a first sealing region; a highly thermally conductive substrate having a second surface having a second sealing region corresponding to the first sealing region and a glass layer formed on the second sealing region, disposed with a predetermined space on the glass substrate so that the second surface faces the first surface; and a sealing layer comprising a melt bonded layer of a glass material for sealing having an electromagnetic wave absorbing property, formed between the first sealing region of the glass substrate and the glass layer so as to airtightly seal the space between the glass substrate and the highly thermally conductive substrate, wherein when the width of the sealing layer is W12 and the width of the glass layer is W2, the width W2 of the glass slayer satisfies the condition of W12<W2.

### Advantageous Effects of Invention

According to the airtight member and its production process of the present invention, when the space between a glass substrate and a highly thermally conductive substrate is airtightly sealed by employing local heating by electromagnetic waves, the bonding property of a sealing layer to the highly thermally conductive substrate and the reliability can be increased. Accordingly, an airtight member in which the space between a glass substrate and a highly thermally conductive substrate is airtightly sealed can be provided with good reproducibility and reliability.

### BRIEF DESCRIPTION OF DRAWINGS

FIG. 1 is a cross-sectional view illustrating an airtight member according to an embodiment of the present invention.

FIG. 2 is a cross-sectional view illustrating an enlarged view of a part of the airtight member as shown in FIG. 1.

FIG. 3 is a cross-sectional view illustrating a process for producing an airtight member according to an embodiment of the present invention.

FIG. 4 is a plan view illustrating a glass substrate used in the process for producing an airtight member as shown in FIG. 3.

FIG. 5 is a cross-sectional view along the line A-A in FIG. 4.

FIG. 6 is a plan view illustrating a highly thermally conductive substrate used in the process for producing an airtight member as shown in FIG. 3.

FIG. 7 is a cross cross-sectional view along the line A-A in FIG. 6.

### DESCRIPTION OF EMBODIMENTS

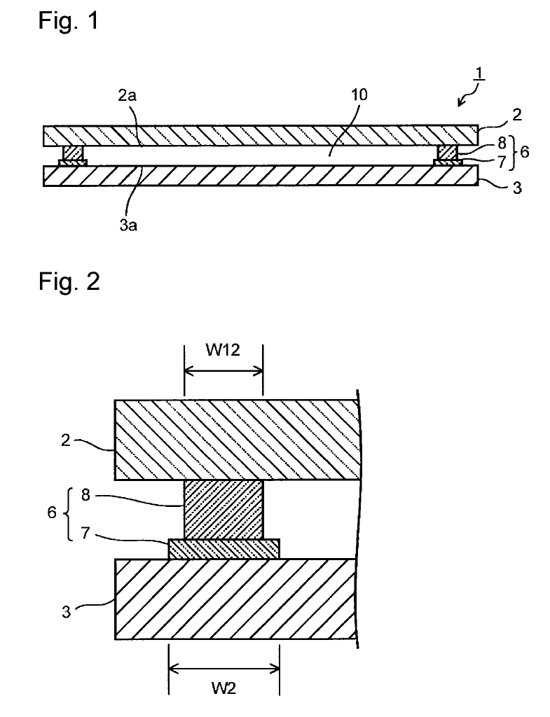

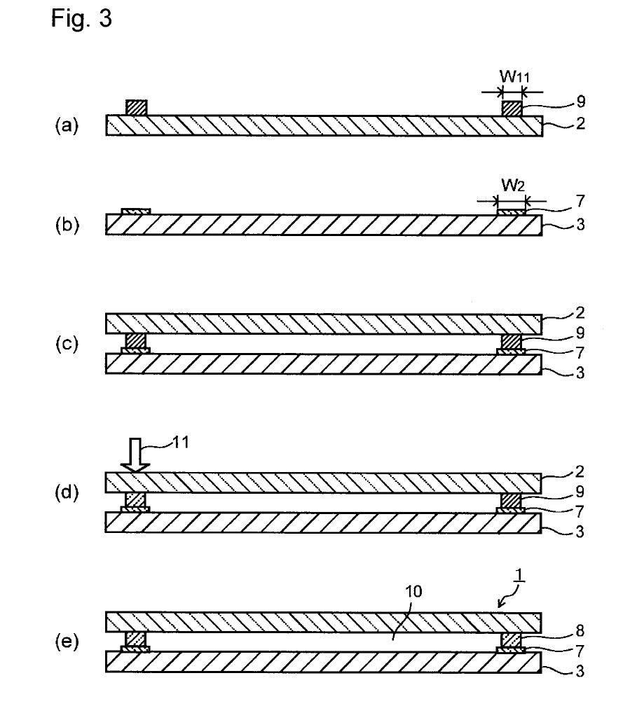

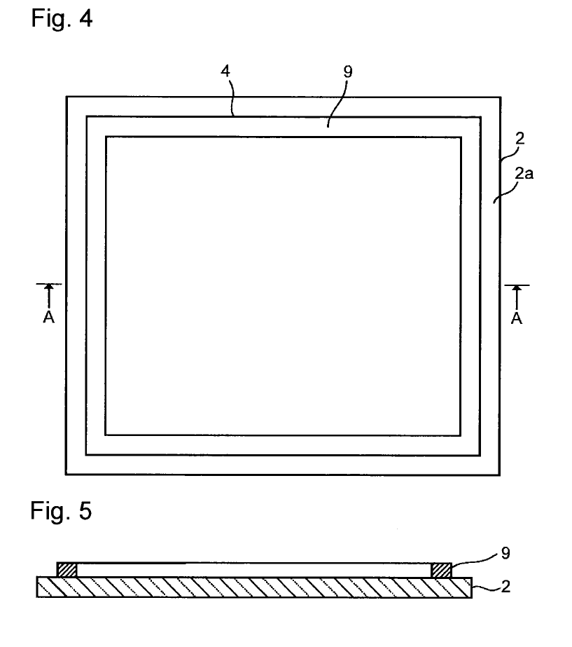

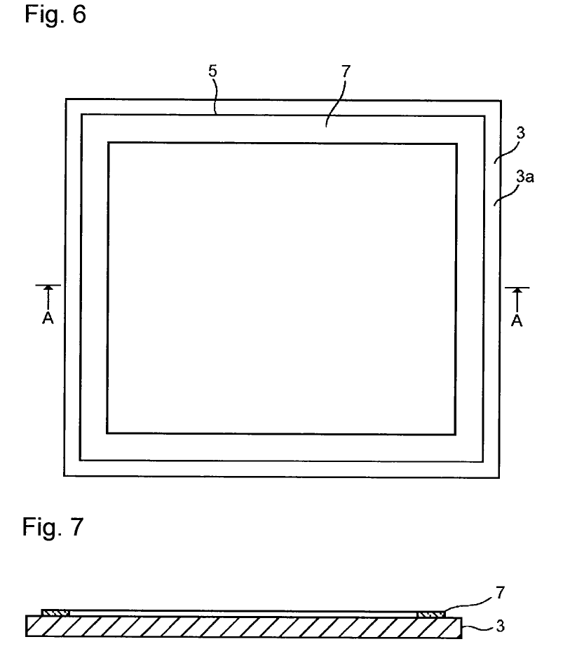

Now, the embodiment of the present invention will be described with reference to drawings. FIG. 1 is a view illustrating the structure of an airtight member according to an embodiment of the present invention, and FIG. 2 is a view illustrating an enlarged view of a part of the airtight member as shown in FIG. 1. FIG. 3 is a view illustrating a process for producing an airtight member according to an embodiment of the present invention, FIGS. 4 and 5 are views illustrating the structure of a glass substrate used in the process for producing an airtight member, and FIGS. 6 and 7 are views illustrating the structure of a highly thermally conductive substrate used in the process for producing an airtight member.

An airtight member 1 shown in FIG. 1 comprises a glass substrate 2 and a highly thermally conductive substrate 3. The material constituting the glass substrate 2 is not particularly limited, and it may, for example, be soda lime glass, alkali-free glass, silicate glass, borate glass, borosilicate glass or phosphate glass, having various known compositions. Such a glass substrate 2 has a coefficient of thermal conductivity at a level of from 0.5 to 1 W/m·K for example. Further, soda lime glass has a coefficient of thermal expansion at a level of from 80 to 90 (×10⁻⁷/° C.), and alkali-free glass has a coefficient of thermal expansion at a level of from 35 to 40 (×10⁻⁷/° C.).

In this specification, “to” used to show the range of the numerical values is used to include the numerical values before and after it as the lower limit value and the upper limit value, and unless otherwise specified, the same applies hereinafter.

The highly thermally conductive substrate 3 may, for example, be a metal substrate, a ceramic substrate or a semiconductor substrate. The highly thermally conductive substrate 3 is a substrate having a coefficient of thermal conductivity at least higher than that of the glass substrate 2, and is particularly preferably a substrate having a coefficient of thermal conductivity of at least 2 W/m·K. For the highly thermally conductive substrate 3, various metal substrates may be used depending upon e.g. the purpose of use of the airtight member 1, and for example, a substrate made of a metal single substance such as aluminum, copper, iron, nickel, chromium or zinc, or an alloy of a combination including at least one of them, may be mentioned. The same applies to the ceramic substrate and the semiconductor substrate, and their constituting materials are not particularly limited. For example, the ceramic substrate may, for example, be a substrate made of an alumina sintered product, a silicon nitride sintered product, an aluminum nitride sintered product, a silicon carbide sintered product or a low temperature co-fired ceramic (LTCC), and the semiconductor substrate may, for example, be a silicon substrate.

In the process for producing an airtight member of the present invention, it is optimal that the glass substrate 2 has a coefficient of thermal conductivity of from 0.5 to 1 W/m·K, and the highly thermally conductive substrate 3 is a substrate having a coefficient of thermal conductivity higher than that of the glass substrate 2, particularly a coefficient of thermal conductivity of from 1.2 to 250 W/m·K.

On the outer peripheral region of the surface 2a of the glass substrate 2, as shown in FIG. 4, a frame-form first sealing region 4 is provided. On the outer peripheral region of the surface 3a of the highly thermally conductive substrate 3, as shown in FIG. 6, a frame-form second sealing region 5 corresponding to the first sealing region 4 is provided. The above frame-form first sealing region 4 and frame-form second sealing region 5 are preferably formed over the entire periphery in the outer peripheral region of the glass substrate 2 and the highly thermally conductive substrate 3. The glass substrate 2 and the highly thermally conductive substrate 3 are disposed with a predetermined space so that the surface 2a having the first sealing region 4 and the surface 3a having the second sealing region 5 face each other. The space between the glass substrate 2 and the highly thermally conductive substrate 3 is properly set depending upon e.g. the purpose of use of the airtight member 1, and for example, a space at a level of from 10 to 200 μm may be provided.

The space between the glass substrate 2 and the highly thermally conductive substrate 3 is sealed with a sealing portion 6. That is, the sealing portion 6 is formed between the sealing region 4 of the glass substrate 2 and the sealing region 5 of the highly thermally conductive substrate 3 so as to airtightly seal the space between the glass substrate 2 and the highly thermally conductive substrate 3. The sealing portion 6 is constituted in the layer structure by a glass layer 7 preliminarily provided on the sealing region 5 of the highly thermally conductive substrate 3 and a sealing layer 8 preliminarily provided on the sealing region 4 of the glass substrate 2. The sealing layer 8 is a melt bonded layer of a glass material for sealing as described in detail hereinafter, and it is directly attached (that is, bonded) to the first sealing region 4 on the glass substrate 2, and is attached (that is, bonded) to the glass layer 7 preliminarily provided on the second sealing region 5 on the highly thermally conductive substrate 3.

The sealing layer 8 is a melt bonded layer formed in such a manner that as shown in FIGS. 3 to 5, a sealing material layer 9 formed on the sealing region 4 of the glass substrate 2 is irradiated with electromagnetic waves such as laser light or infrared ray to locally heat and melt the sealing material layer 9 thereby to bond it to the sealing region 4 of the glass substrate 2 and the glass layer 7. The sealing layer 8 is formed by laminating the glass substrate 2 and the highly thermally conductive substrate 3 so that the sealing material layer 9 (see FIGS. 4 and 5) provided on the glass substrate 2 and the glass layer 7 (see FIGS. 6 and 7) formed on the highly thermally conductive substrate 3 are in contact with each other, and irradiating the sealing material layer 9 with electromagnetic waves such as laser light or infrared ray through the glass substrate 2.

To airtightly seal the space between the glass substrate 2 and the highly thermally conductive substrate 3 by employing local heating by electromagnetic waves such as laser light or infrared ray, if the sealing material layer 9 is in contact with the highly thermally conductive substrate 3, heat generated in the sealing material layer 9 at the time of irradiation with electromagnetic waves will directly be transmitted to the highly thermally conductive substrate 3. Accordingly, the sealing material layer 9 cannot favorably be bonded to the highly thermally conductive substrate 3. Further, a stress applied to the glass substrate 2 or the sealing layer 8 tends to be significant due to thermal expansion based on a difference in thermal conductivity between the sealing material layer 9 and the highly thermally conductive substrate 3, and cracks, breakage or the like is likely to form on the glass substrate 2 or the sealing layer 8. Such may cause a decrease in the strength at the sealing portion and the reliability.

Accordingly, in the airtight member 1 according to this embodiment, a glass layer 7 is preliminarily formed on the sealing region 5 of the highly thermally conductive substrate 3, and the edge on the highly thermally conductive substrate 3 side of the sealing material layer 9 is brought into contact with the glass layer 7. Further, as shown in FIG. 2, both edges in the width direction of the sealing material layer 9 are preferably located inside both edges in the width direction of the glass layer 7, whereby heat generated in the sealing material layer 9 at the time of irradiation with electromagnetic waves will not directly be transmitted to the highly thermally conductive substrate 3, and is shielded with the glass layer 7 having a coefficient of thermal conductivity at the same level as the sealing material layer 9. Accordingly, at the time of irradiation with electromagnetic waves, the sealing material layer 9 can favorably be heated and melted. Accordingly, it is possible to favorably bond the sealing layer 8 comprising the melt bonded layer of the sealing material layer 9 and the glass layer 7 formed on the sealing region 5 of the highly thermally conductive substrate 3.

Further, in the airtight member 1 of this embodiment, between the highly thermally conductive substrate 3 and the sealing material layer 9 (or the sealing layer 8), a glass layer 7 having a coefficient of thermal conductivity at the same level as the glass substrate 2 and the sealing material layer 9 (or the sealing layer 8) is formed, whereby the difference in thermal conductivity between the glass substrate 2 or the sealing material layer 9 (or the sealing layer 8), and the highly thermally conductive substrate 3. Accordingly, it is possible to reduce a stress formed on the glass substrate 2 or the sealing layer 8 due to excessive thermal expansion of the highly thermally conductive substrate 3 side as compared with the glass substrate 2. Therefore, cracks, breakage or the like on the glass substrate 2 and the sealing layer 8 can be suppressed.

As described above, in airtight sealing of the space (airtight space) between the glass substrate 2 and the highly thermally conductive substrate 3 by employing local heating by electromagnetic waves, by preliminarily forming the glass layer 7 on the sealing region 5 of the highly thermally conductive substrate 3, the space 3 between the glass substrate 2 and the highly thermally conductive substrate 3 can be airtightly sealed with good reproducibility with the sealing portion 6 constituted by the glass layer 7 and the sealing layer 8. Further, it is possible to suppress cracks, breakage or the like on the glass substrate 2 and the sealing layer 8 formed by the difference in thermal conductivity between the glass substrate 2 and the highly thermally conductive substrate 3 and thermal expansion based on the difference at the time of sealing by electromagnetic waves. Accordingly, productivity of an airtight member in which the space between the glass substrate 2 and the highly thermally conductive substrate 3 is airtightly sealed can be increased and in addition, the airtight sealing property and the reliability can be improved.

In order to obtain an effect to suppress heat transmission to the highly thermally conductive substrate 3 by the glass slayer 7, the glass layer 7 preferably has a thickness of at least 20 μm. If the glass layer 7 is too thin, heat transmission to the highly thermally conductive substrate 3 may not sufficiently be suppressed. The thickness of the glass layer 7 is more preferably at least 25 μm. Further, the width (that is, the width corresponding to the line width of the frame-form sealing region 5) W2 of the glass layer 7 is preferably broader than the line width W12 (and the line width W11 of the sealing material layer 9 as described hereinafter) of the sealing layer 8, whereby the effect to suppress heat transmission to the highly thermally conductive substrate 3 can be increased.

The line width W2 of the glass layer 7 is more preferably at least 1.1 times the line width W12 of the sealing layer 8 (1.1W12≦W2). Further, the line width W2 of the glass layer 7 is more preferably at least 1.1 the line width W11 of the sealing material layer 9 as described hereinafter (1.1W11≦W2). Further, when the line width from the centerline in the width direction of the glass layer 7 is W2/2 and the line width from the centerline in the width direction of the sealing layer 8 (sealing material layer 9) is W1/2, it is preferred that (W2/2)>(W1/2), and that both edges in the width direction of the sealing layer 8 (sealing material layer 9) are located inside the width direction of the glass layer, whereby the effect to suppress heat transmission to the highly thermally conductive substrate 3 can be more increased. Here, the upper limit of the line width W2 of the glass layer 7 is not particularly limited, and as the case requires, the glass layer 7 may be formed on the entire surface 3a of the highly thermally conductive substrate 3. However, in a case where only the effect to suppress heat transmission by the glass layer 7 is expected, even if the line width W2 of the glass layer 7 is too broad, not only a higher effect cannot be expected any more but also the production cost and the like will be increased. In such a case, the line width W2 of the glass layer 7 is preferably at most 5 times the line width W12 of the sealing layer 8 (and the line width W11 of the sealing material layer 9 as described hereinafter) (W2<5W12). Further, the line width W2 of the glass layer 7 is preferably at most 5 times the line width W11 of the sealing material layer 9 as described hereinafter (W2<5W11).

In the airtight member 1 as shown in FIG. 1, in the space airtightly sealed with the glass substrate 2, the highly thermally conductive substrate 3 and the sealing portion 6, i.e. in the airtight space 10, for example, an electronic element such as a quartz oscillator, a piezoelectric element, a filter element, a sensor element, an imaging element, an organic EL element or a solar battery element, or a reflective film constituting a reflecting mirror is disposed. In a case where an electronic element is disposed in the airtight space 10, the airtight member 1 functions as an airtight package of the electronic element, and the whole constitutes an electronic device. Further, in a case where a reflective film such as a silver film is formed on the surface 2a of the glass substrate 2 and is disposed in the airtight space 10, the airtight member 1 functions as an airtight package of the reflective film, and the whole constitutes a reflecting mirror. The airtight member 1 is not limited to an airtight package of various members, and may be used as a multiple layered component having the airtight space 10.

In a case where the airtight member 1 is used as an airtight package of an electronic element, the electronic element is provided on at least one of the glass substrate 2 and the highly thermally conductive substrate 3 depending upon its own structure, properties and the like. For example, an organic EL element is formed on the highly thermally conductive substrate 3 so that the light emitting surface is on the glass substrate 2 side. Further, a solar battery element is formed on the glass substrate 2 or the highly thermally conductive substrate 3 so that the light-receiving surface is on the glass substrate 2 side. Depending upon the structure of a solar battery element, an element film or the like is formed on each of the glass substrate 2 and the highly thermally conductive substrate 3. The structure of an electronic element disposed in the airtight member 1 is not particularly limited, and various known structures are applicable.

Now, the process for producing an airtight member 1 according to an embodiment will be described with reference to FIG. 3. First, a glass material for sealing to be a material forming a sealing material layer 9 is prepared. The glass material for sealing comprises sealing glass (i.e. glass frit) comprising low-melting glass and having an electromagnetic wave absorber (i.e. a material which absorbs electromagnetic waves such as laser light or infrared ray and generates heat) and a filler such as a low expansion filler added. In a case where the sealing glass itself has an electromagnetic wave absorbing property, addition of the electromagnetic wave absorber may be omitted. The glass material for sealing may contain other additives as the case requires.

The sealing glass (glass frit) may, for example, be low-melting glass such as tin-phosphate glass, bismuth glass, vanadium glass, lead glass or zinc borate alkali glass. Among them, considering the bonding property to the glass substrate 2 and the glass layer 7 and the reliability (the bonding reliability and the airtight sealing property) and further, influences over the environment and the body, etc., it is preferred to use sealing glass comprising tin-phosphate glass or bismuth glass.

The tin-phosphate glass (glass frit) preferably has a composition comprising, as represented by mol % as calculated as the following oxides, from 55 to 68 mol % of SnO, from 0.5 to 5 mol % of SnO₂ and from 20 to 40 mol % of P₂O₅ (basically the total amount is 100 mol %). SnO is a component to make the glass have a low-melting point. If the SnO content is less than 55 mol %, the viscosity of the glass tends to be high, whereby the sealing temperature tends to be too high, and if it exceeds 68 mol %, the glass will not be vitrified.

SnO₂ is a component to stabilize the glass. If the SnO₂ content is less than 0.5 mol %, SnO₂ will be separated and precipitated in the softened and molten glass at the time of sealing operation, whereby the fluidity will be impaired, thus lowering the sealing operation property. If the SnO₂ content exceeds 5 mol %, SnO₂ is likely to be precipitated during melting of the low-melting glass. P₂O₅ is a component to form a glass network. If the P₂O₅ content is less than 20 mol %, the glass will not be vitrified, and if the content exceeds 40 mol %, deterioration of the weather resistance, which is a drawback characteristic to the phosphate glass may be brought about.

Here, the proportions (mol %) of SnO and SnO₂ in the glass frit can be determined as follows. First, the glass frit (low-melting glass powder) is decomposed with an acid, and the total amount of Sn atoms contained in the glass frit is measured by ICP emission spectroscopy. Then, since the amount of Sn²⁺ (SnO) decomposed with an acid can be determined by iodometric titration, the amount of Sn²⁺ determined is subtracted from the total amount of Sn atoms to determine the amount of Sn⁴⁺ (SnO₂).

The glass formed by the above three components has a low glass transition point and is suitable as a sealing material for low temperature, and it may contain, as optional components, a component to form a glass network such as SiO₂, or a component to stabilize the glass such as ZnO, B₂O₃, Al₂O₃, WO₃, MoO₃, Nb₂O₅, TiO₂, ZrO₂, Li₂O, Na₂O, K₂O, Cs₂O, MgO, CaO, SrO or BaO. However, if the content of the optional components is too high, the glass tends to be unstable, thus leading to devitrification, or the glass transition point or the softening point may be increased, and accordingly the total content of the optional components is preferably at most 30 mol %. In such a case, the glass composition is adjusted so that the total amount of the basic components and the optional components is basically 100 mol %.

The bismuth glass (glass frit) preferably has a composition comprising, as represented by mass % as calculated as the following oxides, from 70 to 90 mass % of Bi₂O₃, from 1 to 20 mass % of ZnO and from 2 to 12 mass % of B₂O₃ (basically the total amount is 100 mass %). Bi₂O₃ is a component to form a glass network. If the Bi₂O₃ content is less than 70 mass %, the softening point of the low-melting glass tends to be high, whereby sealing at low temperature tends to be difficult. If the Bi₂O₃ content exceeds 90 mass %, the glass will hardly be vitrified and in addition, the coefficient of thermal expansion tends to be too high.

ZnO is a component to lower the coefficient of thermal expansion and the like. If the ZnO content is less than 1 mass %, vitrification tends to be difficult. If the ZnO content exceeds 20 mass %, the stability at the time of forming the low-melting glass tends to be low, and devitrification is likely to occur. B₂O₃ is a component to form a glass network and to broaden a range within which vitrification is possible. If the B₂O₃ content is less than 2 mass %, vitrification tends to be difficult, and if it exceeds 12 mass %, the softening point tends to be too high, and sealing at low temperature tends to be difficult even when a load is applied at the time of sealing.

The glass formed by the above three components has a low glass transition point and is suitable as a sealing material for low temperature, and it may contain an optional component such as Al₂O₃, CeO₂, SiO₂, Ag₂O, MoO₃, Nb₂O₃, Ta₂O₅, Ga₂O₃, Sb₂O₃, Li₂O, Na₂O, K₂O, Cs₂O, CaO, SrO, BaO, WO₃, P₂O₅ or SnO. (wherein x is 1 or 2). However, if the content of the optional components is too high, the glass tends to be unstable, thus leading to devitrification, or the glass transition point or the softening point may be increased. Accordingly, the total content of the optional components is preferably at most 30 mass %. In such a case, the glass composition is adjusted so that the total amount of the basic components and the optional components is basically 100 mass %.

As the low expansion filler, it is preferred to use at least one member selected from the group consisting of silica, alumina, zirconia, zirconium silicate, cordierite, a zirconium phosphate compound, soda lime glass and borosilicate glass. The zirconium phosphate compound may be (ZrO)₂P₂O₇, NaZr₂(PO₄)₃, KZr₂(PO₄)₃, Ca_{0.5}Zr₂(PO₄)₃, NbZr(PO₄)₃, Zr₂(WO₃)(PO₄)₂, or a composite compound thereof. The low expansion filler is one having a coefficient of thermal expansion lower than that of the sealing glass. The content of the low expansion filler is properly set so that the coefficient of thermal expansion of the sealing glass is close to that of the glass substrate 2. The low expansion coefficient is preferably contained in a range of from 0.1 to 50 vol % based on the glass material for sealing, depending upon the coefficients of linear expansion of the sealing glass and the glass substrate 2.

As the electromagnetic wave absorber, at least one member of at least one metal (including an alloy) selected from Fe, Cr, Mn, Co, Ni and Cu, an oxide containing at least one metal among the above metals, and a compound such as FeO, Fe₂O₃, CoO, Co₂O₃, Mn₂O₃, MnO or CuO is used. It may be another pigment. The content of the electromagnetic wave absorber is preferably within a range of from 0.1 to 40 vol % based on the glass material for sealing. If the content of the electromagnetic wave absorber is less than 0.1 vol %, the sealing material layer 9 may not sufficiently be melted. If the content of the electromagnetic wave absorber exceeds 40 vol %, local heat generation may occur in the vicinity of the interface with the glass layer 7, and the fluidity at the time of melting the glass material for sealing may be deteriorated, whereby the bonding property to the glass layer 7 may be lowered.

Then, the above glass material for sealing is mixed with a vehicle to prepare a sealing material paste. The vehicle is one having a resin as a binder component dissolved in a solvent. The resin for the vehicle may be an organic resin such as a cellulose resin such as methylcellulose, ethylcellulose carboxymethylcellulose, oxyethylcellulose, benzylcellulose, propylcellulose or nitrocellulose, or an acrylic resin obtained by polymerizing at least one acrylic monomer such as methyl methacrylate, ethyl methacrylate, butyl methacrylate, 2-hydroxyethyl methacrylate, butyl acrylate or 2-hydroxyethyl acrylate. The solvent may be, in the case of a cellulose resin, a solvent such as terpineol, butyl carbitol acetate or ethyl carbitol acetate, and in the case of an acrylic resin, a solvent such as methyl ethyl ketone, terpineol, butyl carbitol acetate or ethyl carbitol acetate.

The viscosity of the sealing material paste is a viscosity corresponding to an apparatus for application to the glass substrate 2, and is adjusted by the proportion of the resin (i.e. the binder component) and the solvent and the proportion of the component of the glass material for sealing and the vehicle. To the sealing material paste, known additives for a glass paste such as a defoaming agent or a dispersing agent may be added. For preparation of the sealing material paste, a known method using a rotational mixing machine equipped with a stirring blade, a roll mill or a ball mill may be employed.

As shown in FIG. 3(a), the sealing material paste is applied to the sealing region 4 of the glass substrate 2 and dried to form a coating layer of the sealing material paste. The sealing material paste is applied to the sealing region 4 employing a printing method such as screen printing or gravure printing for example, or applied along the sealing region 4 using a dispenser or the like. The coating layer of the sealing material paste is preferably dried for example at a temperature of at least 120° C. for at least 10 minutes. The drying step is carried out to remove the solvent in the coating layer. If the solvent remains in the coating layer, the binder component may not sufficiently be removed in the firing step.

Then, the coating layer of the sealing material paste is fired to form a sealing material layer 9. In the firing step, the coating layer is heated to a temperature of at most the glass transition of the sealing glass (glass frit) to remove the binder component and the like in the coating layer, and then it is heated to a temperature of at least the softening point of the sealing glass (glass frit) to melt and bake the glass material for sealing to the glass substrate 3. In such a manner, a sealing material layer 9 comprising a fired layer of the glass material for sealing is formed on the sealing region 4 of the glass substrate 2.

The difference in the coefficient of thermal expansion between the sealing material layer and the glass substrate [(the coefficient of thermal expansion of the sealing material layer)-(the coefficient of thermal expansion of the glass substrate)] is preferably within a range of from (−30) to (+70) (×10⁻⁷/° C.), with a view to suppressing significant warpage, cracks and the like.

Then, as shown in FIG. 3(b), a glass layer 7 is formed on the sealing region 5 of the highly thermally conductive substrate 3. The glass material for forming the glass layer 7 may be the above-described sealing glass, or may be another glass frit. Such glass frit may, for example, be SiO₂—B₂O₃-REO (RE: alkaline earth metal, REO: alkaline earth metal oxide) type, SiO₂—B₂O₃—PbO type, B₂O₃—ZnO—PbO type, SiO₂—ZnO-REO type, SiO₂-REO type, SiO₂—PbO type, SiO₂—B₂O₃—R₂₀ (R: alkali metal) type, SiO₂—B₂O₃—Bi₂O₃ type, B₂O₃—ZnO—Bi₂O₃ type, SiO₂—ZnO—R₂₀ type or B₂O₃—Bi₂O₃ type.

The glass layer 7 preferably has a coefficient of thermal expansion close to that of the highly thermally conductive substrate 3 so as to suppress significant warpage, cracks and the like of the highly thermally conductive substrate 3 at the time of firing. The difference in the coefficient of thermal expansion between the glass layer 7 and the highly thermally conductive substrate 3, i.e. [(the coefficient of thermal expansion of the glass layer 7)-(the coefficient of thermal expansion of the highly thermally conductive substrate 3)] depends on the thickness of the glass layer 7, and is preferably within a range of from (−80) to (+40) (×10⁻⁷/° C.), more preferably from (−60) to (+15) (×10⁻⁷/° C.), within a range of the thickness of the glass layer 7 of from 20 μm to 50 μm. For example, in a case where the thickness of the glass layer 7 is 20 μm, the thermal expansion different is preferably within a range of from (−80) to (+40) (×10⁻⁷/° C.), and in a case where the thickness of the glass layer 7 is 25 μm, it is preferably within a range of from (−70) to (+30) (×10⁻⁷/° C.). When the glass layer 7 is thin, warpage and the like may sometimes be suppressed even if the thermal expansion different is significant. In a case where a metal substrate is used as the highly thermally conductive substrate 3, the glass layer 7 has a lower coefficient of thermal expansion than the highly thermally conductive substrate 3 in many cases. In a case where a ceramic substrate such as alumina is used as the highly thermally conductive substrate 3, the glass layer 7 has a coefficient of thermal expansion at the same level as the highly thermally conductive substrate 3, or a coefficient of thermal expansion higher than that of the highly thermally conductive substrate 3 in many cases. In this specification, the coefficients of thermal expansion of the glass substrate, the highly thermally conductive substrate, the sealing material layer, the sealing layer and the glass layer are average coefficients of thermal expansion within a range of from 50 to 250° C., and sometimes referred to simply as the coefficient of thermal expansion (50 to 250° C.).

The highly thermally conductive substrate usually has a higher coefficient of thermal expansion as compared with a glass substrate. From the viewpoint of the thermal expansion matching, the relation of the coefficient of thermal expansion of the sealing material layer 9 and the glass layer 7 is preferably such that [the coefficient of thermal expansion of the sealing material layer 9]<[the coefficient of thermal expansion of the glass layer 7].

The glass layer 7 may contain an electromagnetic wave absorber, whereby the bonding property to the sealing layer 8 will be improved. However, if the glass paste contains a filler such as an electromagnetic wave absorber, the surface smoothness of the glass layer 7 may be lowered. The surface smoothness of the glass layer 7 influences the adhesion to the sealing layer 8 as described hereinafter, and from such a viewpoint, it is preferred that a filler such as an electromagnetic wave absorber is not contained. It is preferred to determine whether a filler is added or not considering these points comprehensively.

As the glass material for formation of the glass layer 7, the above-described glass frit is mixed with a vehicle in the same manner as the step of preparing the sealing material paste to prepare a glass paste. To the glass paste, a filler to adjust the coefficient of thermal expansion may be added. Such a glass paste is applied to the sealing region 5 of the highly thermally conductive substrate 3 and dried to form a coating layer of the glass paste. Application of the glass plate is carried out in the same manner as the step of applying the sealing material paste. Further, it is preferred to carry out a drying step after application. Then, the coating layer of the glass paste is heated to a temperature of at most the glass transition point of the glass frit to remove the binder component in the coating layer, and then heated to a temperature of at least the softening point of the glass frit to melt the glass frit and to bake the coating layer to the highly thermally conductive substrate 3. In such a manner, on the sealing region 5 of the highly thermally conductive substrate 3, a glass layer 7 comprising a fired layer of the glass frit is formed.

In a case where the highly thermally conductive substrate 3 is a ceramic substrate having heat resistance such as an alumina substrate, the firing temperature when the coating layer of the glass paste is baked can be set high. For example, in a case where an alumina substrate is used, firing at a temperature in the vicinity of 1,000° C. is possible. Accordingly, high-melting glass frit may be used. On the other hand, in a case where the highly thermally conductive substrate 3 is a metal substrate, firing at a relatively low temperature is preferred so as to suppress warpage at the time of firing. Accordingly, the softening point of the glass frit is preferably low. Specifically, the softening of the glass fit is preferably at most 600° C., more preferably at most 400° C.

The glass layer 7 preferably has a thickness of at least 20 μm as described above. Further, the line width W2 of the glass layer 7 is preferably broader than the line width W11 of the sealing material layer 9 (that is, W11<W2), and is more preferably at least 1.1 times the line width W11 of the sealing material layer 9 (that is, 1.1W11≦W2), whereby when the sealing material layer 9 is irradiated with electromagnetic waves, transmission of heat generated in the sealing material layer 9 to the highly thermally conductive substrate 3 can effectively be suppressed.

Further, the surface of the glass layer 7 is preferably smooth so as to increase the adhesion to the sealing layer 8. The surface roughness of the glass layer 7 is preferably at most 0.8 μm by the arithmetic mean roughness Ra. To make the surface of the glass layer 7 smooth, it is preferred to conduct application of the glass paste dividedly in several times, or to carry out a leveling treatment after application of the glass paste. The leveling treatment is carried out, for example, by leaving the coating film of the glass paste for a predetermined time before the drying step. By conducting application of the glass paste dividedly in several times, a relatively thick glass layer 7 can be stably formed and at the same time, its surface can be made smooth.

Then, as shown in FIG. 3(c), the glass substrate 2 and the highly thermally conductive substrate 3 are laminated via the sealing material layer 9 so that their surfaces 2a and 3a face each other. The sealing material layer 9 is disposed so as to be in contact with the glass layer 7. Then, as shown in FIG. 3(d), the sealing material layer 9 is irradiated with electromagnetic waves 11 such as laser light or infrared ray through the glass substrate 2 from above the glass substrate 2. In a case where laser light is used as the electromagnetic waves 11, the laser light is applied along the frame-form sealing material layer 9 with scanning. The laser light is not particularly limited, and laser light from a semiconductor laser, a carbon dioxide laser, an excimer laser, a YAG laser, a HeNe laser or the like may be used. In a case where infrared ray is used as the electromagnetic waves 11, it is preferred to selectively irradiate the sealing material layer 9 with infrared ray by masking a portion other than a portion where the sealing material layer 9 is formed with e.g. an infrared reflecting film for example.

In a case where laser light is used as the electromagnetic waves 11, the sealing material layer 9 is melted sequentially from a portion irradiated with laser light applied along the sealing material layer 9 with scanning, and is quickly cooled and solidified simultaneously with completion of irradiation with laser light, and bonded to the glass layer 7. In a case where infrared ray is used as the electromagnetic waves 11, the sealing material layer 9 is locally heated and melted based on irradiation with infrared ray, and is quickly cooled and solidified simultaneously with completion of irradiation with infrared ray and is bonded to the highly thermally conductive substrate 3. In such a manner, as shown in FIG. 3(e), a sealing layer 8 which airtightly seals the space between the glass substrate 2 and the highly thermally conductive substrate 3 (i.e. the airtight space 10) is formed over the entire periphery of the sealing region.

By the airtight member 1 and its production process according to this embodiment, the space between the glass substrate 2 and the highly thermally conductive substrate 3 (i.e. the airtight space 10) can favorably be airtightly sealed with a sealing portion 6 constituted by the glass layer 7 and the sealing layer 8. Further, since the difference in thermal conductivity between the glass substrate 2 and the highly thermally conductive substrate 3 at the time of irradiation with electromagnetic waves 11 is suppressed, cracks, breakage and the like of the glass substrate 2 and the sealing layer 8 due to thermal expansion and a stress based on the difference in thermal conductivity can be suppressed. Therefore, the productivity of an airtight member in which the space between the glass substrate 2 and the highly thermally conductive substrate 3 is airtightly sealed is improved, and the airtight sealing property and the reliability can be improved.

### EXAMPLES

Now, the present invention will be described in detail with reference to Examples. However, it should be understood that the present invention is not limited to following specific Examples, and modification is possible within a range of the scope of the present invention.

### Example 1

First, bismuth glass frit (softening point: 410° C.) having a composition, as calculated as oxides, 83 mass % of Bi₂O₃, 5 mass % of B₂O₃, 11 mass % of ZnO and 1 mass % of Al₂O₃, and having an average particle size (D50) of 1.0 μm, a cordierite powder having an average particle size (D50) of 0.9 μm as a low expansion filler, and a laser absorber having a composition of Fe₂O₃—Al₂O₃—MnO—CuO and having an average particle size (D50) of 0.8 μm, were prepared. The average particle size was measured by using a laser diffraction/scattering particle size measuring apparatus (Microtrac HRA manufactured by NIKKISO CO., LTD.).

67.0 vol % of the bismuth glass frit, 19.1 vol % of the cordierite powder and 13.9 vol % of the laser absorber were mixed to prepare a glass material for sealing for a sealing material layer (hereinafter this will be referred to as low-melting glass material 1). Then, 80 mass % of the glass material for sealing and 20 mass % of a vehicle were mixed to prepare a sealing material paste. The vehicle is one having ethylcellulose (2.5 mass %) as a binder component dissolved in a solvent (97.5 mass %) terpineol.

Then, a glass substrate (dimensions: outer shape 100×100 mm, thickness 0.7 mm) comprising alkali-free glass (coefficient of thermal expansion (50 to 250° C.): 38×10⁻⁷/° C., coefficient of thermal conductivity: 0.7 W/m·k) was prepared, and the sealing material paste was applied by a screen printing method to the entire periphery of the sealing region of the glass substrate. Then, the glass substrate was put in a firing furnace and dried at 120° C. for 10 minutes. Then, the ambient temperature in the firing furnace was raised and the coating layer of the sealing material paste was fired at 480° C. for 10 minutes to form a sealing material layer having a line width of 0.75 mm and a film thickness of 10 μm on the glass substrate. Of the sealing material layer, the coefficient of thermal expansion (50 to 250° C.) was 72×10⁻⁷/° C., and the coefficient of thermal conductivity was 0.9 W/m·K).

77.8 vol % of the above-described bismuth glass frit and 22.2 vol % of the cordierite powder were mixed to prepare a low-melting glass material for a glass layer (hereinafter this will be referred to as low-melting glass material 2). 80 mass % of the low-melting glass material and 20 mass % of the vehicle were mixed to prepare a glass material paste. Then, an alumina substrate (coefficient of thermal expansion (50 to 250° C.): 77×10⁻⁷/° C., coefficient of thermal conductivity: 30 Win K) having the same shape as the glass substrate was prepared as a highly thermally conductive substrate. Using the above glass material paste, a glass layer was formed on the entire periphery of a sealing region of the alumina substrate.

The glass layer was formed as follows. First, the glass material paste was printed on the sealing region of the alumina substrate using a 250 mesh screen (this screen used for printing is represented as #250 in Tables 1 and 2), followed by leveling at 25° C. for 10 minutes, and the glass material paste was dried at 120° C. for 10 minutes. Then, on the coating layer of the glass material paste, the glass material paste was printed again using the 250 mesh screen, followed by leveling at 25° C. for 10 minutes, and the glass material paste was dried at 120° C. for 10 minutes. Then, the coating layer obtained by application of the glass material paste twice was fired at 490° C. for 10 minutes to form a glass layer having a line width of 1 mm, a film thickness of 30 μm and a surface roughness Ra of 0.5 μm. Of the glass layer, the coefficient of thermal expansion (50 to 250° C.) was 72×10⁷/° C., and the coefficient of thermal conductivity was 0.9 W/m·K. Drying of the paste of the glass material and firing of the coating layer were carried out in a firing furnace.

The glass substrate having the sealing material layer and the alumina substrate having the glass layer were laminated so that the sealing material layer and the glass layer are in contact with each other. Then, the sealing material layer was irradiated with laser light (semiconductor laser) having a wavelength of 940 nm and an output power of 52 W through the glass substrate from above the glass substrate with a scanning rate of 10 mm/sec and heated to form a sealing layer. The heating temperature (measured by a radiation thermometer) of the sealing material layer at the time of irradiation with laser was 620° C.

After laser sealing, the appearance of the state of the glass substrate and the sealing layer was observed, whereupon the sealing layer was favorably bonded to the glass layer, and peeling or the like was not confirmed. Further, cracks, breakage or the like was not confirmed on the glass substrate and the sealing layer. The airtightness of the airtight member in which the space between the glass substrate and the alumina substrate was sealed with the sealing portion was evaluated by a helium leak test, whereupon it was confirmed that favorable airtightness was achieved.

### Examples 2 to 7

An airtight member was prepared in the same manner as in Example 1 except that the glass material for sealing, the glass material for forming a glass layer and the highly thermally conductive substrate as identified in Table 1 or 2 were used, and the conditions for producing the glass layer and the laser irradiation conditions as identified in Table 1 were employed. The outer appearance test and the airtightness test for the obtained airtight member were carried out in the same manner as in Example 1. The results are shown in Table 1.

In Table 1, the glass material 3 for forming a glass layer comprises glass frit having a composition comprising 55 mass % of SiO₂, 3 mass % of B₂O₃, 11 mass % of CaO, 18 mass % of SrO, 10.5 mass % of BaO, 0.5 mass % of Na₂O and 2 mass % of ZrO₂, and contains no other filler. Further, the glass material 4 for forming a glass layer comprises glass frit having a composition comprising 27 mass % of SiO₂, 9 mass % of B₂O₃ and 64 mass % of PbO, and contains no other filler.

### Comparative Examples 1 to 3

An airtight member was prepared in the same manner as in Example 1 except that a highly thermally conductive substrate having no glass layer formed thereon as identified in Table 2 was used, and the laser irradiation conditions as identified in Table 2 were employed. The outer appearance test and the airtightness test for the airtight member were carried out in the same manner as in Example 1. The results are shown in Table 2.

TABLE 1

| | | Ex. 1 | Ex. 2 | Ex. 3 | Ex. 4 | Ex. 5 |
|---|---|---|---|---|---|---|
| Glass | Material | Alkali-free glass | | | | |
| substrate | Coefficient of | 0.7 | 0.7 | 0.7 | 0.7 | 0.7 |
| | thermal | | | | | |
| | conductivity | | | | | |
| | [W/m · K] | | | | | |
| Sealing | Material | Low- | Low- | Low- | Low- | Low- |
| material | | melting | melting | melting | melting | melting |
| layer | | glass | glass | glass | glass | glass |
| | | material 1 | material 1 | material 1 | material 1 | material 1 |
| | Line width [mm] | 0.75 | 0.75 | 0.75 | 0.75 | 0.75 |
| | Film thickness | 10 | 10 | 10 | 10 | 10 |
| | [μm] | | | | | |
| Highly | Material | Alumina | Alumina | Aluminum | Aluminum | Aluminum |
| thermally | Coefficient of | 30 | 30 | 237 | 237 | 237 |
| conductive | thermal | | | | | |
| substrate | conductivity | | | | | |
| | [W/m · K] | | | | | |

| Glass | Material | | Low- | Glass | Glass | Glass | Low- |
|---|---|---|---|---|---|---|---|
| layer | | | melting | material 3 | material 4 | material 4 | melting |
| | | | glass | | | | glass |
| | | | material 2 | | | | material 1 |
| | Line width [mm] | | 1 | 1 | 1 | 1 | 1 |
| | Film thickness [μm] | | 30 | 30 | 20 | 50 | 30 |
| | Surface roughness | | 0.5 | 0.1 | 0.1 | 0.1 | 0.3 |
| | Ra [μm] | | | | | | |
| | Production | 1. Printing | #250 | #250 | #250 | #165 | #250 |
| | conditions | 2. Leveling | 25° C. × | 25° C. × | 25° C. × | 25° C. × | 25° C. × |
| | | | 10 min | 10 min | 10 min | 10 min | 10 min |
| | | 3. Drying | 120° C. × | 120° C. × | 120° C. × | 120° C. × | 120° C. × |
| | | | 10 min | 10 min | 10 min | 10 min | 10 min |
| | | 4. Printing | #250 | #250 | #250 | #165 | #250 |
| | | 5. Leveling | 25° C. × | 25° C. × | 25° C. × | 25° C. × | 25° C. × |
| | | | 10 min | 10 min | 10 min | 10 min | 10 min |
| | | 6. Drying | 120° C. × | 120° C. × | 120° C. × | 120° C. × | 120° C. × |
| | | | 10 min | 10 min | 10 min | 10 min | 10 min |
| | | 7. Firing | 490° C. × | 950° C. × | 590° C. × | 590° C. × | 490° C. × |
| | | | 10 min | 10 min | 10 min | 10 min | 10 min |

| Sealing | Laser output (W) | | 52 | 48 | 32 | 21 | 48 |
|---|---|---|---|---|---|---|---|
| step | Laser scanning rate | | 10 | 10 | 5 | 5 | 10 |
| | (mm/s) | | | | | | |
| | Heating temperature | | 620 | 620 | 640 | 640 | 620 |
| | (° C.) | | | | | | |
| Evaluation | Outer | Peeling | Nil | Nil | Nil | Nil | Nil |
| results | appearance | Cracks | Nil | Nil | Nil | Nil | Nil |

| | | | | | |
|---|---|---|---|---|---|
| Airtightness | Observed | Observed | Observed | Observed | Observed |

TABLE 2

| | | | | Comp. | Comp. | Comp |
|---|---|---|---|---|---|---|
| | | Ex. 6 | Ex. 7 | Ex. 1 | Ex. 2 | Ex. 3 |
| Glass | Material | Alkali-free glass | | | | |
| substrate | Coefficient of | 0.7 | 0.7 | 0.7 | 0.7 | 0.7 |
| | thermal | | | | | |
| | conductivity | | | | | |
| | [W/m · K] | | | | | |
| Sealing | Material | Low- | Low- | Low- | Low- | Low- |
| material | | melting | melting | melting | melting | melting |
| layer | | glass | glass | glass | glass | glass |
| | | material 1 | material 1 | material 1 | material 1 | material 1 |
| | Line width [mm] | 0.75 | 0.75 | 0.75 | 0.75 | 0.75 |
| | Film thickness | 10 | 10 | 10 | 10 | 10 |
| | [μm] | | | | | |
| Highly | Material | LTCC | Alumina | Alumina | Aluminum | LTCC |
| thermally | Coefficient of | 3 | 30 | 30 | 237 | 3 |
| conductive | thermal | | | | | |
| substrate | conductivity | | | | | |
| | [W/m · K] | | | | | |

| Glass | Material | | Low- | Low- | (Nil) | (Nil) | (Nil) |
|---|---|---|---|---|---|---|---|
| layer | | | melting | melting | | | |
| | | | glass | glass | | | |
| | | | material 1 | material 2 | | | |
| | Line width [mm] | | 1 | 1 | — | — | — |
| | Film thickness [μm] | | 30 | 30 | — | — | — |
| | Surface roughness | | 0.5 | 0.1 | — | — | — |
| | Ra [μm] | | | | | | |
| | Production | 1. Printing | #250 | #250 | — | — | — |
| | conditions | 2. Leveling | 25° C. × | 25° C. × | — | — | — |
| | | | 10 min | 10 min | | | |
| | | 3. Drying | 120° C. × | 120° C. × | — | — | — |
| | | | 10 min | 10 min | | | |
| | | 4. Printing | #250 | #250 | — | — | — |
| | | 5. Leveling | 25° C. × | 25° C. × | — | — | — |
| | | | 10 min | 10 min | | | |
| | | 6. Drying | 120° C. × | 120° C. × | — | — | — |
| | | | 10 min | 10 min | | | |
| | | 7. Firing | 490° C. × | 950° C. × | — | — | — |
| | | | 10 min | 10 min | | | |

| Sealing | Laser output (W) | | 45 | 60 | 20 to 60 | 20 to 60 | 20 to 60 |
|---|---|---|---|---|---|---|---|
| step | Laser scanning rate | | 10 | 10 | 5 | 5 | 5 |
| | (mm/s) | | | | | | |
| | Heating temperature | | 680 | 640 | 500 to 800 | 500 to 800 | 500 to 800 |
| | (° C.) | | | | | | |
| Evaluation | Outer | Peeling | Nil | Nil | Nil | Observed | Observed |
| results | appearance | Cracks | Nil | Nil | Observed | Observed | Observed |

| | | | | | |
|---|---|---|---|---|---|
| Airtightness | Observed | Observed | — | Nil | Nil |

As evident from Tables 1 and 2, in Examples 1 to 7, the sealing layer can favorable be bonded to the highly thermally conductive substrate via the glass layer. Accordingly, an airtight member in which the space between the glass substrate and the highly thermally conductive substrate is airtightly sealed with the glass layer and the sealing layer can be prepared with high reliability with good reproducibility. Whereas, in Examples 1 to 3, test is carried out on samples wherein the laser output was changed within a range of from 20 to 60 W, however, the sealing layer could not favorably be bonded to the highly thermally conductive substrate, and even if it could be bonded, cracks, breakage or the like was confirmed on the sealing layer or the glass substrate.

### INDUSTRIAL APPLICABILITY

According to the process for producing an airtight member of the present invention, an airtight member in which the space between the glass substrate and the highly thermally conductive substrate is airtightly sealed can be provided with good reproducibility with high reliability, and the present invention is useful for a package in which an electronic element such as a quartz oscillator, piezoelectric element, a filter element, a sensor element, an imaging element, an organic EL element or a solar battery element is airtightly sealed.

This application is a continuation of PCT Application No. PCT/JP2012/054645, filed on Feb. 24, 2012, which is based upon and claims the benefit of priority from Japanese Patent Application No. 2011-041416 filed on Feb. 28, 2011. The contents of those applications are incorporated herein by reference in its entirety.

### REFERENCE SYMBOLS

1: airtight member, 2: glass substrate, 2a: surface, 3: highly thermally conductive substrate, 3a: surface, 4: first sealing region, 5: second sealing region, 6: sealing portion, 7: glass layer, 8: sealing layer, 9: sealing material layer, 10: airtight space, 11: electromagnetic waves

What is claimed is:

1. A process for producing an airtight member, which comprises:
preparing a glass substrate having a first surface having a first sealing region and a sealing material layer comprising a fired layer of a glass material for sealing having an electromagnetic wave absorbing property, formed on the first sealing region;
preparing a highly thermally conductive substrate having a second surface having a second sealing region corresponding to the first sealing region and a glass layer formed on the second sealing region;
laminating the glass substrate and the highly thermally conductive substrate while the first surface and the second surface are brought to face each other and the sealing material layer and the glass layer are brought into contact with each other; and
irradiating the sealing material layer with electromagnetic waves through the glass substrate to locally heat and melt the sealing material layer thereby to bond it to the glass layer, so as to form a sealing layer which airtightly seals the space between the glass substrate and the highly thermally conductive substrate.

2. The process for producing an airtight member according to claim 1, wherein the glass layer has a thickness of at least 20 μm.

3. The process for producing an airtight member according to claim 1, wherein the surface roughness of the glass layer is at most 0.8 μm by the arithmetic mean roughness Ra.

4. The process for producing an airtight member according to claim 1, wherein when the width of the sealing material layer is W11 and the width of the glass layer is W2, the width W2 of the glass layer satisfies the condition of W11<W2.

5. The process for producing an airtight member according to claim 4, wherein the width W2 of the glass layer satisfies the condition of 1.1W11≦W2.

6. The process for producing an airtight member according to claim 1, wherein both the edges in the width direction of the sealing material layer are located inside both the edges in the width direction of the glass layer.

7. The process for producing an airtight member according to claim 1, wherein the highly thermally conductive substrate is a metal substrate, a ceramic substrate or a semiconductor substrate.

8. The process for producing an airtight member according to claim 1, wherein the glass material for sealing contains sealing glass comprising low-melting glass, from 0.1 to 40 vol % of an electromagnetic wave absorber and from 0.1 to 50 vol % of a low expansion filler.

9. The process for producing an airtight member according to claim 1, wherein laser light as the electromagnetic waves is applied along the sealing material layer with scanning.

10. The process for producing an airtight member according to claim 1, wherein the difference in the coefficient of thermal expansion between the glass layer and the highly thermally conductive substrate [(the coefficient of thermal expansion of the glass layer)-(the coefficient of thermal expansion of the highly thermally conductive substrate)] is within a range of from (−80) to (+40) (×10⁻⁷° C.).

11. An airtight member, which comprises:
a glass substrate having a first surface having a first sealing region and a sealing material layer formed of a glass material for sealing having an electromagnetic wave absorbing property on the first sealing region;
a highly thermally conductive substrate having a second surface having a second sealing region corresponding to the first sealing region and a glass layer formed on the second sealing region, disposed with a predetermined space on the glass substrate so that the second surface faces the first surface; and
a sealing layer formed by melting the sealing material layer on the glass substrate to be bonded to the glass layer on the highly thermally conductive substrate so as to airtightly seal the space between the glass substrate and the highly thermally conductive substrate,
wherein when the width of the sealing material layer is W12 and the width of the glass layer is W2, the width W2 of the glass layer satisfies the condition of W12<W2.

12. The airtight member according to claim 11, wherein the glass layer has a thickness of at least 20 μm.

13. The airtight member according to claim 11, wherein the width W2 of the glass layer satisfies the condition of 1.1W12≦W2.

14. The airtight member according to claim 11, wherein the highly thermally conductive substrate is a metal substrate, a ceramic substrate or a semiconductor substrate.

15. The airtight member according to claim 11, wherein the sealing layer is a melt bonded layer of the glass material for sealing containing sealing glass comprising low-melting glass, from 0.1 to 40 vol % of an electromagnetic wave absorber and from 0.1 to 50 vol % of a low expansion filler.
